(19) United States
(12) Patent Application Publication
(10) Pub. No.: US 2024/0297636 A1
(43) Pub. Date: Sep. 5, 2024

(54) Resonator Element And Resonator Device

(71) Applicant: SEIKO EPSON CORPORATION, Tokyo (JP)

(72) Inventors: Takuro KOBAYASHI, Minowa (JP); Akinori YAMADA, Ina (JP); Takashi YAMAZAKI, Shiojiri (JP); Osamu KAWAUCHI, Shiojiri (JP)

(21) Appl. No.: 18/592,642

(22) Filed: Mar. 1, 2024

(30) Foreign Application Priority Data
Mar. 2, 2023 (JP) 2023-031670

(51) Int. Cl. H03H 9/215; H03H 9/19

(52) U.S. Cl. CPC H03H 9/215; H03H 9/19

(57) ABSTRACT

A resonator element includes a base part and a vibrating arm. The vibrating arm includes an arm part and a wide part whose width is larger than that of the arm part. In the arm part, a first groove is formed on the first surface side, and a second groove is formed on the second surface side. 30 μm≤Wa≤75 μm, in which a width of the arm part is Wa, a thickness T between the first surface and the second surface of the arm part satisfies 110 μm≤T≤150 μm. 0.884≤(t1+t2)/T≤0.990, in which a depth of the first groove is t1, and a depth of the second groove is t2. 0.0056≤Wb/T≤0.0326, in which a width of the first surface arranged across the first groove and a width of the second surface arranged across the second groove are Wb. A length L1 of the vibrating arm satisfies L1≤1000 μm.

The present application is based on, and claims priority from JP Application Serial Number 2023-031670, filed Mar. 2, 2023, the disclosure of which is hereby incorporated by reference herein in its entirety.

### BACKGROUND

### 1. Technical Field

The present disclosure relates to a resonator element and a resonator device.

### 2. Related Art

JP-A-2013-229733 discloses that, for a tuning fork type resonator element having bottomed grooves in a vibrating arm, by setting a depth of one bottomed groove opened in one main surface and a depth of the other bottomed groove opened in the other main surface in a predetermined range with respect to a thickness of the vibrating arm, thermoelastic loss can be reduced as compared with the related art. Therefore, a resonator element that can obtain a high Q value and that exhibit excellent vibration characteristics is obtained.

JP-A-2013-229733 is an example of the related art.

However, in the resonator element that is the resonator element in JP-A-2013-229733, an optimum value for increasing the Q value or decreasing a CI value for the depth of the groove is disclosed, but there is a problem that an optimum value for increasing the Q value or decreasing the CI value for a width of land, that is, a width of the main surfaces arranged across the groove is not disclosed.

### SUMMARY

A resonator element including: a base part; and a vibrating arm coupled to the base part, in which the vibrating arm includes an arm part, and a wide part that is located on an opposite side of the arm part from a base part side and whose width is larger than that of the arm part, the arm part includes a first surface, a second surface, a first side surface, and a second side surface, a first groove is formed on a first surface side, and a second groove is formed on a second surface side, 30 μm≤Wa≤75 μm, in which a width of the arm part is Wa, a thickness T between the first surface and the second surface of the arm part satisfies 110 μm≤T≤150 μm, 0.884≤(t1+t2)/T≤0.990, in which a depth of the first groove is t1, and a depth of the second groove is t2, 0.0056≤Wb/T≤0.0326, in which a width of the first surface arranged across the first groove and a width of the second surface arranged across the second groove are Wb, and a length L1 of the vibrating arm satisfies L1≤1000 μm.

A resonator device includes the resonator element described above, and a package that houses the resonator element.

### BRIEF DESCRIPTION OF THE DRAWINGS

FIG. 1 is a plan view showing a configuration of a resonator device according to the embodiment.

FIG. 2 is a cross-sectional view taken along a line A1-A1 in FIG. 1.

FIG. 3 is a plan view showing a configuration of a resonator element according to the embodiment.

FIG. 4 is a cross-sectional view taken along a line A2-A2 in FIG. 3.

FIG. 5 is a diagram showing a relationship between a groove depth and a CI value.

FIG. 6 is a diagram showing a relationship between a width of a first surface and a second surface arranged across grooves and a CI value.

### DESCRIPTION OF EMBODIMENTS

### 1. Embodiment

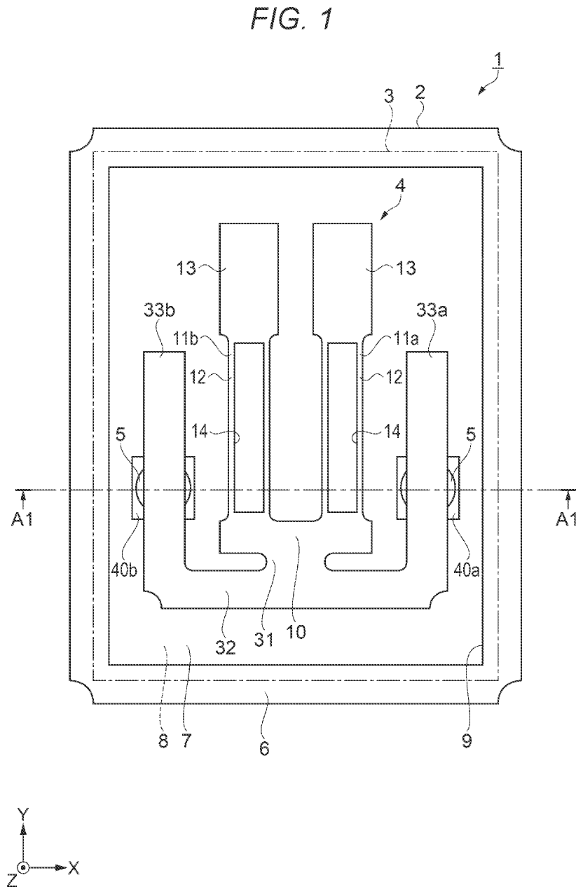

A resonator element 4 and a resonator device 1 including the resonator element 4 according to the embodiment will be described with reference to FIGS. 1 to 6.

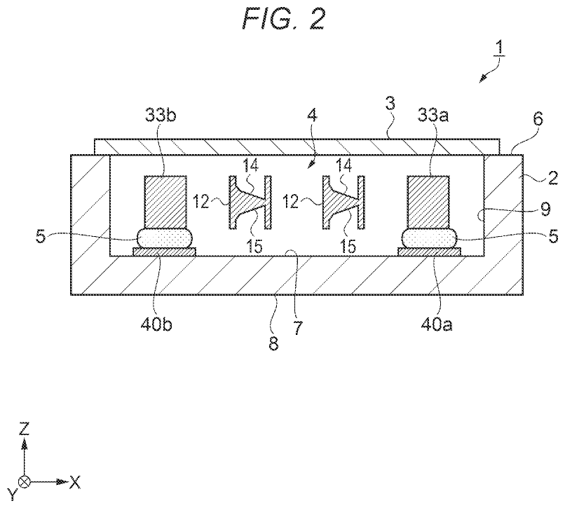

For convenience of description, in each of FIGS. 1 to 4, an X axis, a Y axis, and a Z axis are illustrated as three axes orthogonal to one another. Further, a direction along the X axis is referred to as an “X direction”, a direction along the Y axis is referred to as a “Y direction”, and a direction along the Z axis is referred to as a “Z direction”. Further, an arrow side of each axis is also referred to as a “plus side”, and a side opposite to an arrow is also referred to as a “minus side”. Further, the plus side in the Z direction is also referred to as “upper”, and the minus side in the Z direction is also referred to as “lower”. Further, for convenience of description, illustration of an electrode provided at the resonator element 4 is omitted in FIGS. 1 to 4, and illustration of wiring provided at an inner bottom surface 7 of the package 2 is omitted in FIGS. 1 and 2.

### 1.1. Resonator Device

As shown in FIGS. 1 and 2, the resonator device 1 according to the embodiment includes a tuning fork-shaped resonator element 4, the package 2 that houses the resonator element 4, a lid 3 that is joined to the package 2 and hermetically seals a housing space that houses the resonator element 4, and adhesives 5 that fix the resonator element 4 to the package 2.

The package 2 has a recess 9 opened in an upper surface 6, and the resonator element 4 is housed in the recess 9. At the inner bottom surface 7 of the package 2, the resonator element 4 is fixed via the conductive adhesives 5, and internal terminals 40a and 40b electrically coupled to the electrode (not shown) provided at the resonator element 4 are disposed. At a lower surface 8 of the package 2, an external terminal electrically coupled to the internal terminals 40a and 40b by wiring (not shown) is disposed.

The resonator element 4 is disposed such that substantially central parts of support arms 33a and 33b, which are disposed on both sides in the X direction in which a base part 10 and a pair of vibrating arms 11a and 11b are sandwiched, in the Y direction overlap the internal terminals 40a and 40b, more specifically, such that the support arm 33a overlaps the internal terminal 40a and the support arm 33b overlaps the internal terminal 40b, and is fixed to the inner bottom surface 7 of the package 2 via the conductive adhesives 5.

Therefore, when the electrode provided at the resonator element 4 and the external terminal are electrically coupled to each other and a drive signal is applied to the external terminal, tip ends of the vibrating arms 11a and 11b can be subjected to flexural vibration in the X direction by repeatedly approaching and separating from each other.

The lid 3 has a flat plate shape, and is joined to the upper surface 6 of the package 2 via a joining member such as solder or low-melting-point glass such that inside of the recess 9 that houses the resonator element 4 is hermetically sealed.

### 1.2. Resonator Element

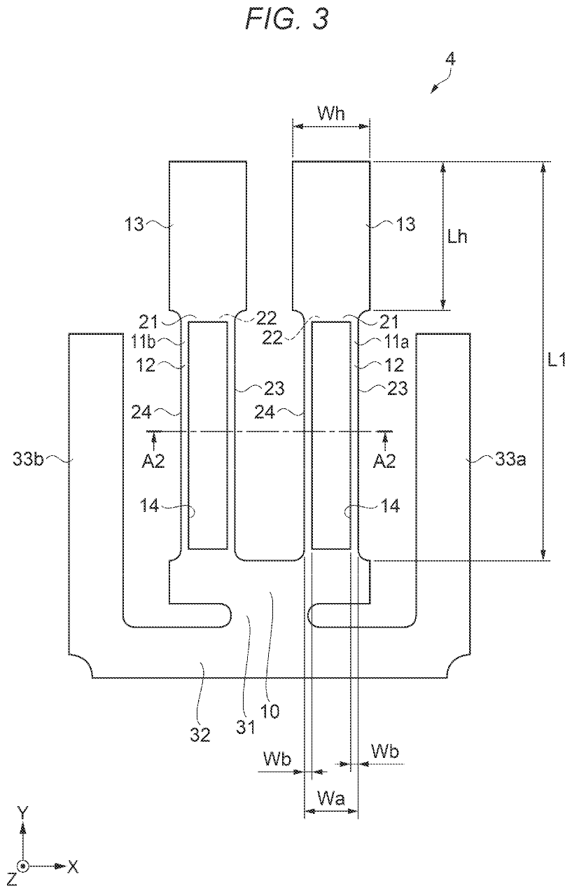

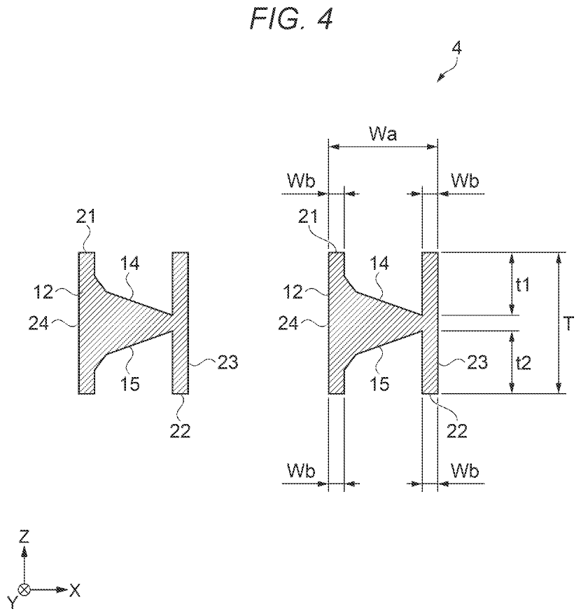

As shown in FIGS. 3 and 4, the resonator element 4 provided in the resonator device 1 according to the embodiment has the tuning fork shape including the pair of support arms 33a and 33b that sandwich the base part 10 and the pair of vibrating arms 11a and 11b and that are coupled to the base part 10.

The resonator element 4 is formed by patterning a Z-cut quartz crystal substrate into a desired shape, has a spread in an X-Y plane defined by the X axis and the Y axis that are crystal axes of quartz crystal, and has a thickness along the Z direction.

The resonator element 4 includes the base part 10, the pair of vibrating arms 11a and 11b that extend from the base part 10 to the plus side in the Y direction and that are arranged in the X direction, and the pair of support arms 33a and 33b that is coupled to the minus side in the Y direction of the base part 10, that extend to the plus side in the Y direction, and that are arranged in the X direction. The vibrating arm 11a and the support arm 33a are located on the plus side in the X direction, and the vibrating arm 11b and the support arm 33b are located on the minus side in the X direction.

The vibrating arms 11a and 11b each include an arm part 12, and a wide part 13 that is located on an opposite side of the arm part 12 from a base part 10 side. In the wide part 13, a width that is a length in the X direction is wider than that of the arm part 12.

The arm part 12 includes a first surface 21, a second surface 22, a first side surface 23, and a second side surface 24, and is formed with a bottomed first groove 14 opened in the first surface 21 on a first surface 21 side and a bottomed second groove 15 opened in the second surface 22 on a second surface 22 side.

The first groove 14 and the second groove 15 extend in the Y direction. Further, as shown in FIG. 4, cross sections of the first groove 14 and the second groove 15 have a shape in which a crystal plane of the quartz crystal appears. This is because the resonator element 4 is formed by wet etching. Since an etching rate in the minus X direction is lower than an etching rate in the plus X direction due to etching anisotropy of the quartz crystal, a side surface in the minus X direction has a relatively gentle inclination, and a side surface in the plus X direction has a nearly perpendicular inclination.

The support arms 33a and 33b are coupled to tip end parts of a support part 32, which extends from a coupling part 31 coupled to the minus side in the Y direction of the base part 10 to the plus side in the X direction and the minus side in the X direction, and extend to the plus side in the Y direction. The support arm 33a is coupled to the tip end part of the support part 32 on the plus side in the X direction, and the support arm 33b is coupled to the tip end part of the support part 32 on the minus side in the X direction. Therefore, by fixing the substantially central parts of the support arms 33a and 33b in the Y direction, as compared with a case where the related-art base part 10 is fixed by the adhesives 5, a distance from the vibrating arms 11a and 11b to the fixing parts can be sufficiently increased, and an influence of vibration leakage from the vibrating arms 11a and 11b and distortion from the adhesives 5 can be reduced.

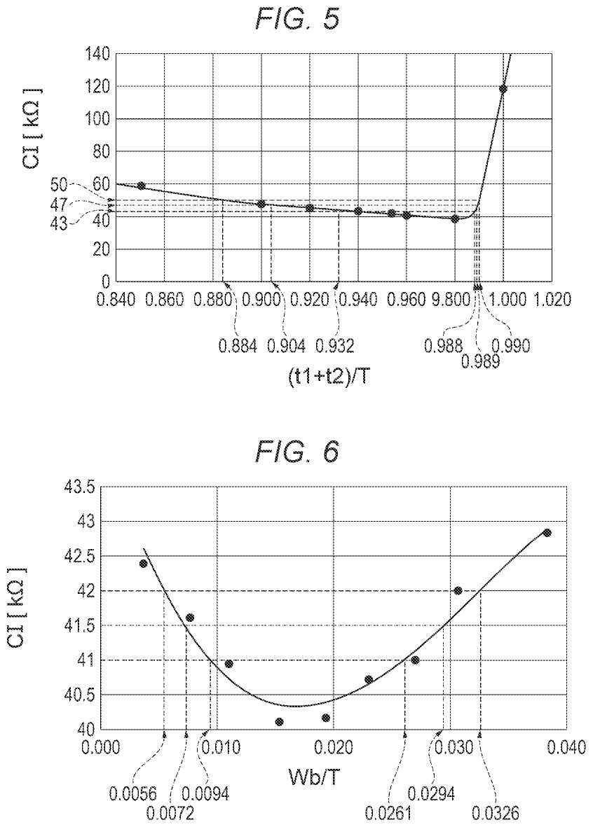

Next, optimum values of dimensions for reducing the CI value of the resonator element 4 will be described with reference to FIGS. 5 and 6.

FIGS. 5 and 6 show simulation results. In the following description, a simulation using the resonator element 4 formed by patterning the Z-cut quartz crystal substrate and having a flexural vibration frequency (mechanical flexural vibration frequency) f=32.768 kHz will be representatively used. However, discoverers have confirmed that, in the range of the flexural vibration frequency f of 32.768 kHz±1 kHz, there is almost no difference from simulation results shown below.

In the present simulation, the resonator element 4 obtained by patterning the quartz crystal substrate by wet etching is used. Therefore, as described above, the cross sections of the first groove 14 and the second groove 15 have the shape in which the crystal plane of the quartz crystal appears as in FIG. 4.

The vibrating arms 11a and 11b of the resonator element 4 used in the present simulation each have the length L1 of 993 μm, a thickness T of 130 μm, and a width Wa of 70 μm. The discoverers have confirmed that there is almost no difference from simulation results shown below when the length L1 is within a range of 500 μm to 1000 μm with L1≤1000 μm, the thickness T is within a range of 110 μm to 150 μm, and the width Wa is within a range of 30 μm to 75 μm. Further, the resonator element 4 in which no electrode is formed is used in the present simulation.

FIG. 5 shows simulation results indicating a relationship between the CI value and (t1+t2)/T obtained by adding a maximum depth t1 of the first groove 14 and a maximum depth t2 of the second groove 15 and standardizing an added result by the thickness T. With reference to FIG. 5, when 0.884≤(t1+t2)/T≤0.990 is satisfied, the CI value of the resonator element 4 can be reduced to 50 kΩ or less. This is considered to be because when (t1+t2)/T is 0.884 or more, a facing area between side-surface electrodes provided at the first side surface 23 and the second side surface 24 of the arm part 12 and groove electrodes provided in the first groove 14 and the second groove 15 is sufficiently secured, an electric field efficiency of a part sandwiched by the side-surface electrode and the groove electrode is improved, and the CI value is reduced. Further, it is considered that, when (t1+t2)/T is 0.990 or less, a part sandwiched by the first groove 14 and the second groove 15 remains to some extent, rigidity of the vibrating arms 11a and 11b is secured, unnecessary vibration such as oblique vibration can be reduced, vibration efficiency of the flexural vibration that is main vibration is improved, and the CI value is reduced.

When 0.904≤(t1+t2)/T≤0.989 is satisfied, the CI value of the resonator element 4 can be reduced to 47 kΩ or less. Further, when 0.932≤(t1+t2)/T≤0.988 is satisfied, the CI value of the resonator element 4 can be further reduced to 43 kΩ or less.

FIG. 6 shows simulation results indicating a relationship between the CI value and Wb/T obtained by standardizing, by the thickness T, a width Wb of the first surfaces 21 arranged across the first groove 14 and the width Wb of the second surfaces 22 arranged across the second groove 15. With reference to FIG. 6, when 0.0056≤Wb/T≤0.0326 is satisfied, the CI value of the resonator element 4 can be reduced to 42 kΩ or less. It is considered that, when Wb/T is 0.0056 or more, the rigidity of the vibrating arms 11a and 11b is secured, the unnecessary vibration such as oblique vibration can be reduced, the vibration efficiency of the flexural vibration that is the main vibration is improved, and the CI value is reduced. Further, it is considered that, when Wb/T is 0.0326 or less, an interval between the side-surface electrode and the groove electrode is secured to some extent, the electric field efficiency of the part sandwiched by the side-surface electrode and the groove electrode is improved, and the CI value is reduced.

When 0.0072≤Wb/T≤0.0294 is satisfied, the CI value of the resonator element 4 can be further reduced to 41.5 kΩ or less. Further, when 0.0094≤Wb/T≤0.0261 is satisfied, the CI value of the resonator element 4 can be further reduced to 41 kΩ or less.

When the thickness T between the first surface 21 and the second surface 22 of the arm part 12 is smaller than 110 μm, the depth t1 of the first groove 14 and the depth t2 of the second groove 15 become small, and the facing area between the side-surface electrode and the groove electrode cannot be sufficiently secured. Therefore, it is difficult to reduce the CI value. Further, when the thickness T is larger than 150 μm, it is necessary to increase the width Wa of the arm part 12 in order to satisfy 0.884≤(t1+t2)/T≤0.990, and it becomes difficult to miniaturize the resonator element 4. The thickness T preferably satisfies 120 μm≤T≤140 μm. Further, the thickness T more preferably satisfies 125 μm≤T≤135 μm.

A width Wh of the wide part 13 preferably satisfies 130 μm≤Wh≤190 μm. When the width Wh is smaller than 130 μm, mass effect cannot be sufficiently exhibited. When the width Wh is larger than 190 μm, an interval between the two wide parts 13 becomes narrow, and the vibrating arms 11a and 11b are likely to break when the wide parts 13 come into contact with each other. Therefore, when the width Wh satisfies 130 μm≤Wh≤190 μm, the mass effect can be sufficiently exhibited, and the miniaturization can be achieved.

A length Lh of the wide part 13 preferably satisfies 200 μm≤Lh≤400 μm. When the length Lh is smaller than 200 μm, the mass effect cannot be sufficiently exhibited. When the length Lh is larger than 400 μm, the length L1 of the vibrating arms 11a and 11b increases, and the miniaturization becomes difficult. Therefore, when the length Lh satisfies 200 μm≤Lh≤400 μm, the mass effect can be sufficiently exhibited, and the miniaturization can be achieved.

As described above, in the resonator element 4 and the resonator device 1 including the resonator element 4 according to the embodiment, a relationship between the depth t1 of the first groove 14 and the depth t2 of the second groove 15 and the thickness T satisfies 0.884≤(t1+t2)/T≤0.990, and a relationship between the width Wb of the first surface 21 and the second surface 22 and the thickness T satisfies 0.0056≤Wb/T≤0.0326. Therefore, the electric field efficiency of the part sandwiched by the side-surface electrode and the groove electrode is improved, the rigidity of the vibrating arms 11a and 11b is secured, the unnecessary vibration such as oblique vibration can be reduced, the vibration efficiency of the flexural vibration that is the main vibration is improved, and the CI value can be reduced. Therefore, it is possible to obtain the small-sized resonator element 4 and resonator device 1 with a small CI value.

What is claimed is:

1. A resonator element comprising:
a base part; and
a vibrating arm coupled to the base part, wherein
the vibrating arm includes
an arm part, and
a wide part that is located on an opposite side of the arm part from a base part side and whose width is larger than that of the arm part,
the arm part includes a first surface, a second surface, a first side surface, and a second side surface,
a first groove is formed on a first surface side, and a second groove is formed on a second surface side,
30 μm≤Wa≤75 μm, wherein a width of the arm part is Wa,
a thickness T between the first surface and the second surface of the arm part satisfies 110 μm≤T≤150 μm,
0.884≤(t1+t2)/T≤0.990, wherein a depth of the first groove is t1, and a depth of the second groove is t2,
0.0056≤Wb/T≤0.0326, wherein a width of the first surface arranged across the first groove and a width of the second surface arranged across the second groove are Wb, and
a length L1 of the vibrating arm satisfies L1≤1000 μm.

2. The resonator element according to claim 1, wherein
0.904≤(t1+t2)/T≤0.989.

3. The resonator element according to claim 1, wherein
0.932≤(t1+t2)/T≤0.988.

4. The resonator element according to claim 1, wherein
0.0072≤Wb/T≤0.0294.

5. The resonator element according to claim 1, wherein
0.0094≤Wb/T≤0.0261.

6. The resonator element according to claim 1, wherein
a width Wh of the wide part satisfies 130 μm≤Wh≤190 μm.

7. The resonator element according to claim 1, wherein
a length Lh of the wide part satisfies 200 μm≤Lh≤400 μm.

8. The resonator element according to claim 6, wherein
a length Lh of the wide part satisfies 200 μm≤Lh≤400 μm.

9. The resonator element according to claim 1, wherein
the thickness T satisfies 120 μm≤T≤140 μm.

10. The resonator element according to claim 4, wherein
the thickness T satisfies 120 μm≤T≤140 μm.

11. The resonator element according to claim 1, wherein
the thickness T satisfies 125 μm≤T≤135 μm.

12. The resonator element according to claim 4, wherein
the thickness T satisfies 125 μm≤T≤135 μm.

13. A resonator device comprising:
the resonator element according to claim 1; and
a package that houses the resonator element.
